(19) United States
(12) Patent Application Publication
(10) Pub. No.: US 2018/0079265 A1
(43) Pub. Date: Mar. 22, 2018

(54) INTERNAL TIRE WINDMILL ENERGY HARVESTER

(71) Applicant: Bridgestone Americas Tire Operations, LLC, Nashville, TN (US)

(72) Inventor: Paul B. Wilson, Tallmadge, OH (US)

(21) Appl. No.: 15/564,441

(22) PCT Filed: Mar. 23, 2016
(86) PCT No.: PCT/US16/23755

§ 371 Date: Oct. 5, 2017

Related U.S. Application Data
(60) Provisional application No. 62/143,910, filed on Apr. 7, 2015.

(51) Int. Cl. B60C 23/04; B81B 7/02; H02N 11/00

(52) U.S. Cl. CPC B60C 23/041; B29D 2030/0094; H02N 11/002; B81B 7/02

(57) ABSTRACT

Electrical system may be configured to operate inside a tire mounted to a wheel. Electrical system may include a plurality of microelectromechanical system (MEMS) devices including a gas flow energy receiver mechanically coupled to at least one base. Each gas flow energy receiver may be operatively coupled to at least one generator. Generator may be configured to convert gas flow energy to electrical energy. Generator may be configured to direct the electrical energy to an electrical output. The electrical system may include a support feature. The support feature may be configured to mount the at least one base of the plurality of MEMS devices to one or more of an inner surface of the tire or an inner surface of the wheel. The plurality of MEMS devices may be mounted effective to place the gas flow energy receivers in a gas flow space of the tire mounted to the wheel.

### BACKGROUND

There is much current interest in placing various electronic devices, such as sensors, actuators, and radio devices inside tires to monitor and report on tire health and operating parameters, to actively adapt tire performance characteristics, and the like. An in-tire power source is highly desirable for these types of devices, and alternatives to traditional batteries are sought.

The present application appreciates that providing a source of electrical power inside of a rotating vehicle tire may be a challenging endeavor.

### SUMMARY

In one embodiment, an electrical system configured to operate inside a tire mounted to a wheel is provided. The electrical system may include a plurality of microelectromechanical system (MEMS) devices. Each MEMS device may include a gas flow energy receiver mechanically coupled to at least one base. Each gas flow energy receiver may be operatively coupled to at least one generator. The at least one generator may be configured to convert gas flow energy to electrical energy. The at least one generator may be configured to direct the electrical energy to an electrical output of the at least one generator. The electrical system may include a support feature. The support feature may be configured to mount the at least one base of the plurality of MEMS devices to one or more of an inner surface of the tire or an inner surface of the wheel. The plurality of MEMS devices may be mounted effective to place the gas flow energy receivers in a gas flow space of the tire mounted to the wheel. The gas flow space may be defined between the inner surfaces of the wheel and the tire mounted to the wheel.

In another embodiment, an electrical system configured to operate inside a tire mounted to a wheel is provided. The electrical system may include one or more gas flow power devices. The one or more gas flow power devices may each include a gas flow energy receiver mechanically coupled to a base. The gas flow energy receiver may be operatively coupled to at least one generator. The at least one generator may be configured to convert received gas flow energy to electrical energy. The at least one generator may direct the electrical energy to an electrical output of the at least one generator. The electrical system may include a hoop configured to mount the at least one base of the plurality of gas flow power devices to one or more of an inner surface of the tire or an inner surface of the wheel. The plurality of gas flow power devices may be mounted effective to place the gas flow energy receivers in a gas flow space of the tire mounted to the wheel. The gas flow space may be defined between the inner surfaces of the wheel and the tire mounted to the wheel.

In one embodiment, a method for operating an electrical system inside a tire mounted to a wheel is provided. The method may include providing the tire mounted to the wheel. A gas flow space may be defined between the inner surfaces of the wheel and the tire. The method may include providing a gas flow caused at least in part by relative motion. The relative motion may be between: gas in the gas flow space; and an inner surface of the tire and/or an inner surface of the wheel. The method may include receiving a portion of gas flow energy from the gas flow using a microelectromechanical system (MEMS) device to produce a portion of mechanical energy. The MEMS device may include a gas flow energy receiver. The method may include converting the mechanical energy using an electrical generator to electrical energy. The method may include directing the electrical energy to an output of the electrical generator.

### BRIEF DESCRIPTION OF THE DRAWINGS

The accompanying figures, which are incorporated in and constitute a part of the specification, illustrate example methods and apparatuses, and are used merely to illustrate example embodiments.

FIG. 1 depicts a side view of a tire showing computational fluid dynamics of gas flow.

FIG. 2A depicts a cross-section of a top of a tire showing computational fluid dynamics of gas flow.

FIG. 2B depicts a cross-section of a footprint region of a tire showing computational fluid dynamics of gas flow.

FIG. 3A depicts a side view of a tire illustrating gas flow.

FIG. 3B is a graph showing gas flow velocity versus radius.

FIG. 4A illustrates a tire-wheel in cross section.

FIG. 4B is a graph showing gas flow velocity at a footprint region of a tire versus radius.

FIG. 5A is a block diagram of an example electrical system.

FIG. 5B illustrates an example electrical system configured to operate inside a tire mounted to a wheel.

FIG. 5C illustrates a plurality of MEMS windmills.

FIG. 5D is a block diagram of an example electrical system.

FIG. 6A is a block diagram of an example electrical system.

FIG. 6B illustrates an example electrical system configured to operate inside a tire mounted to a wheel.

FIG. 6C is a block diagram of an example electrical system.

FIG. 7 is a flow diagram of an example method of operating an electrical system.

### DETAILED DESCRIPTION

This document describes electrical systems configured to convert energy of fluid motion, such as a gas, to electrical energy. Such systems may be configured to operate inside a tire mounted to a wheel. For example, a pneumatic tire-wheel may be inflated with a gas, e.g., air. Rotation of the tire/wheel may cause motion of the gas within, for example, by relative motion between the inner surfaces of the tire and/or wheel and the gas, by deformation of the tire during rotation of the tire through a contact patch with the ground on which the tire may roll, and the like. The electrical energy may be used to power any of a variety of electronics used within, on, or about the tire and/or wheel, for example, sensors, controllers, actuators, data recorders, communications modules, and the like. Generation of electrical energy from fluid motion energy of a gas within a pneumatic tire may allow such electrical systems and associated electronics to operate without batteries, power sources external to the tire/wheel, and the like.

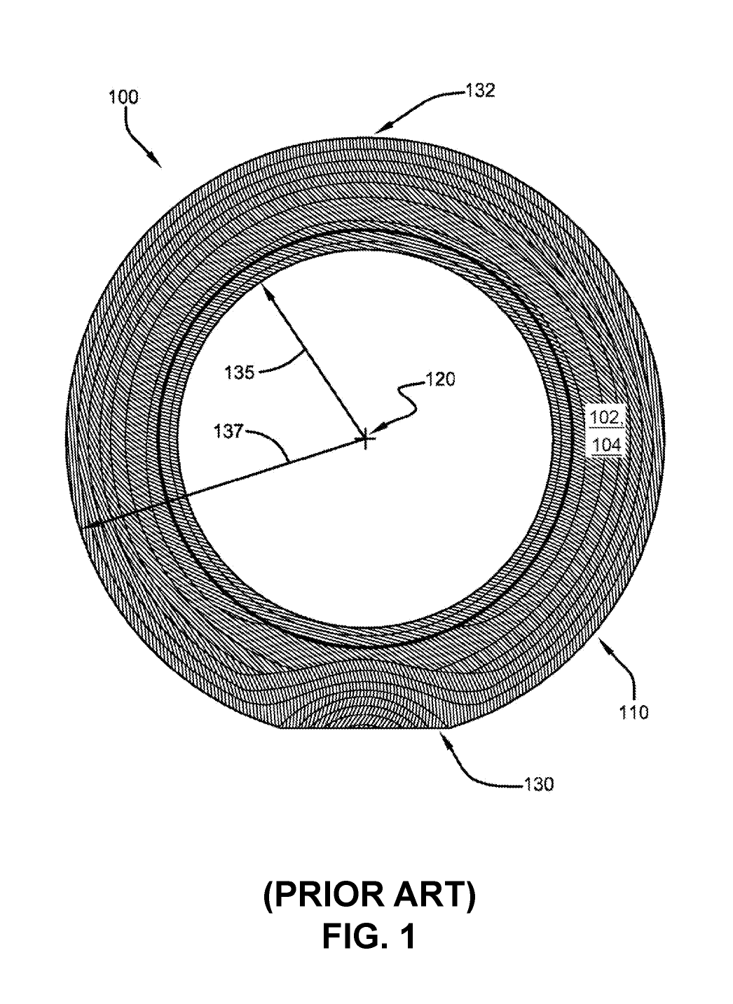

The fluid motion of an inflation gas within a pneumatic tire as described below for prior art FIGS. 1, 2A, 2B, 3A, 3B, 4A, and 4B has been modeled and described, for example, in Steenwyk et al., WO2013148432, the entire contents of which are incorporated herein by reference.

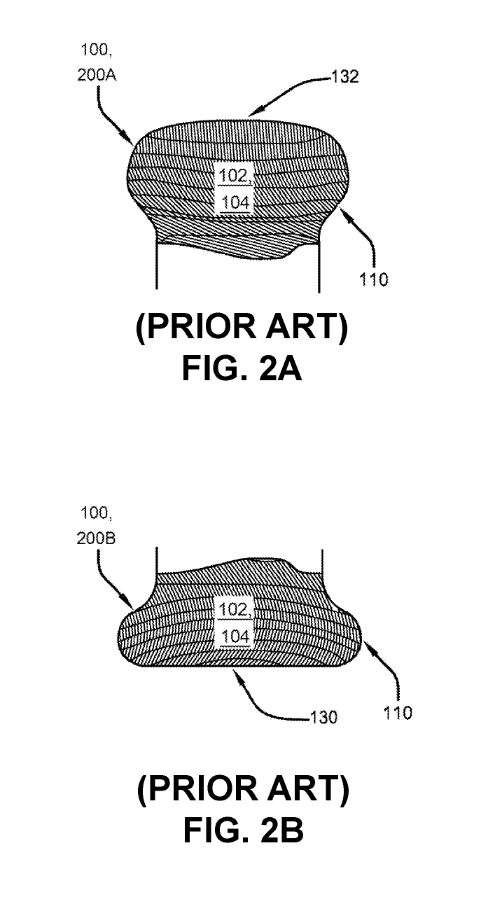

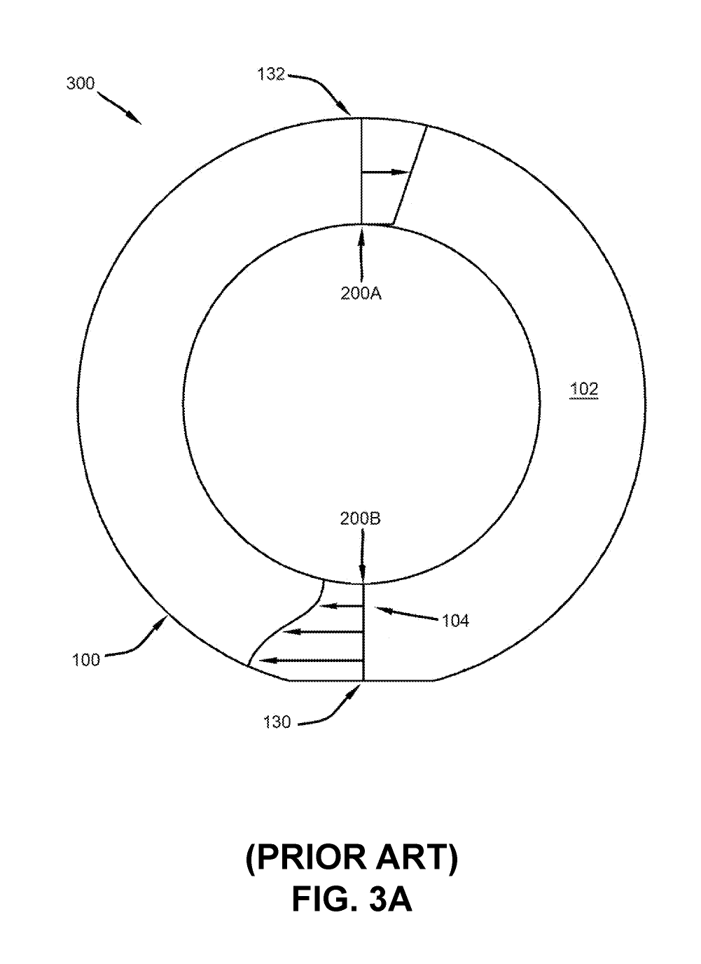

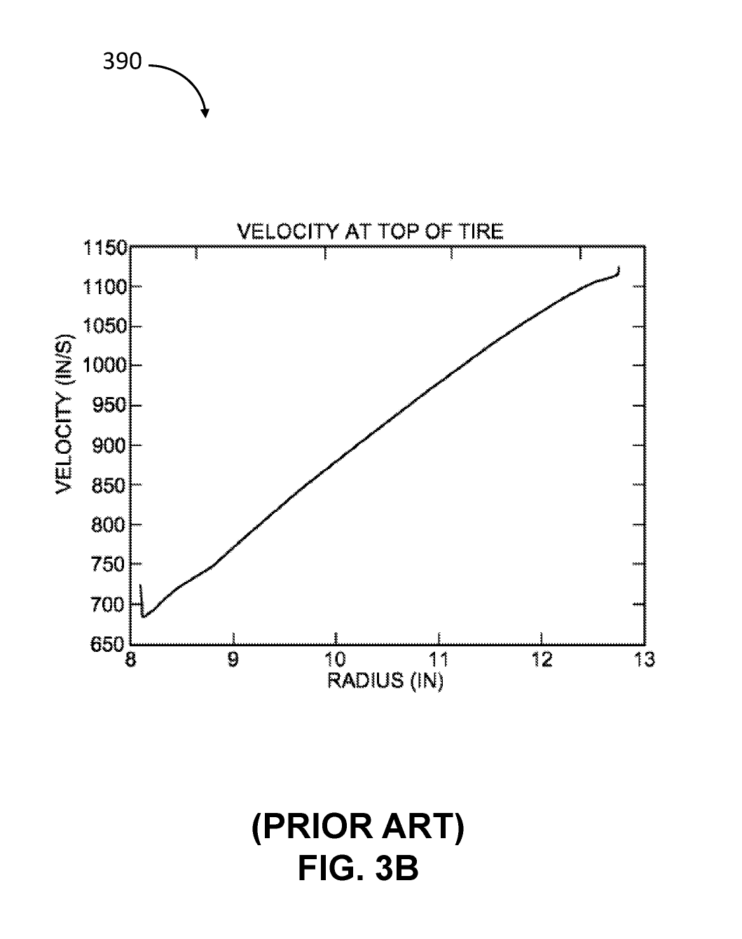

Briefly, FIG. 1 illustrates a side view of an example tire 100 showing graphic computational fluid dynamics results 110. FIGS. 2A and 2B illustrate these same computational fluid dynamics results 110 from cross-section 200A proximate to a crown 132 of tire 100 and cross-section 200B proximate to a footprint region 130 of tire 100, respectively. FIG. 3A illustrates a side view 300 of tire 100 showing inflation gas 102, fluid flow 104, crown footprint region 130, and crown 132. Computational fluid dynamics results 110 in FIGS. 1, 2A and 2B show velocity of a fluid flow corresponding to fluid flow 104 of inflation gas 102 throughout tire 100 in FIG. 3A. As used herein unless otherwise noted, “gas” means any gas used for inflation of a pneumatic tire, for example, atmospheric air, shop air, dry air, nitrogen, carbon dioxide, noble gases such as helium, neon, argon, and krypton or other gases, mixtures thereof, and the like. Similarly, fluid flow 104 may refer to flow of any such gas or mixture thereof.

Referring again to FIGS. 1, 2A, and 2B, computational fluid dynamics results 110 are based on assumptions of a P215/55R17 passenger size tire rotating in a 10 foot diameter drum, at 65 mph under a 1146 lbf load and inflated with shop air as inflation gas 102 to 30.5 psi cold and 33.4 psi hot. While the specific results shown in FIGS. 1, 2A, and 2B may depend on the above assumptions, the general trends and findings herein are not specific to any particular tire, tire size, speed, load, inflation gas, roadway or inflation pressure. In FIGS. 1, 2A, and 2B, the calculated flow velocity at any given point based on the above assumptions may be a function of two variables: 1) radial distance from an axis of rotation 120 of tire 100; 2) proximity to footprint region 130. Gas flow velocity may be slower closer to axis of rotation 120 of tire 100 compared to flow further from axis of rotation 120. For example, in regions distal from footprint region 130, the flow along inner radius 135 may be approximately 715 inches per second. Further, for example, in regions distal from the footprint region 130, the flow along outer radius 137 may be approximately 1142 inches per second. In general, in regions distal from the footprint region 130, the flow velocity may be described as a positive function of radial position, with flow velocity increasing with increasing radius. The flow velocity as a function of proximity to footprint region 130 at any given radial position may be substantially faster than flow at the same radial position in regions distal from the footprint region 130. In general, in regions proximate to footprint region 130, flow velocity may be described as a positive function of radial position and proximity to the center of the footprint, with flow velocity increasing with increasing radius and/or increasing proximity to the center of footprint region 130.

Returning to FIG. 3A, in operation, tire 100 may rotate and roll or slide along a roadway (not shown). Also, during operation tire 100 may operate under a load, e.g., a vehicle load, such as some fraction of the weight of a vehicle (not shown), a cargo load (not shown), a dynamic load (not shown), the weight of tire 100 and an associated wheel (not shown), and the like. Such a load may result in deformation of the tire region contacting the roadway into tire footprint 130.

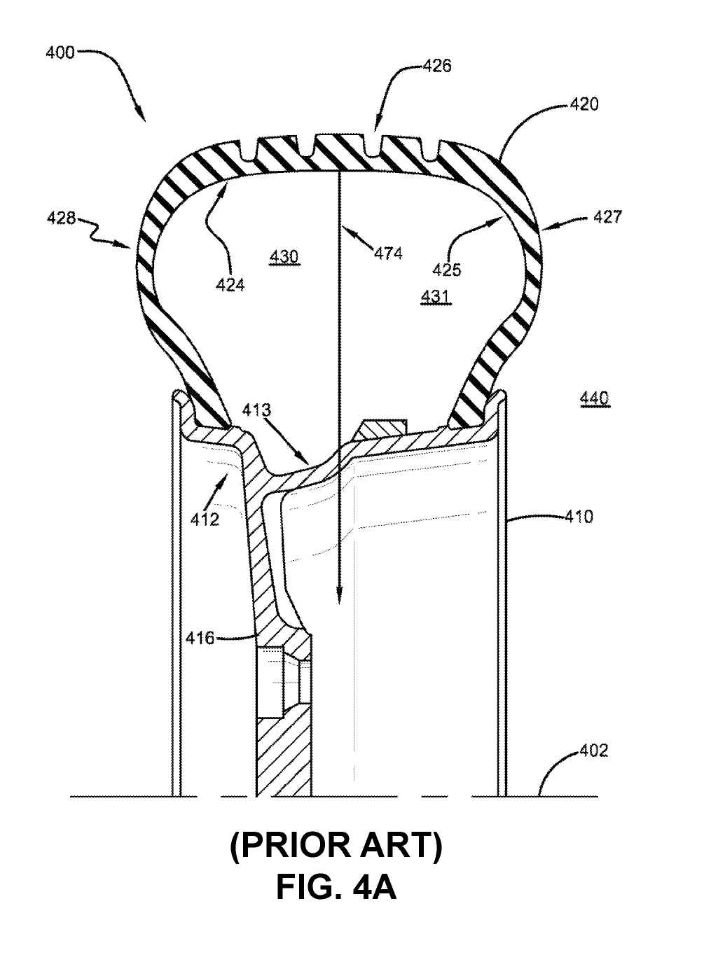

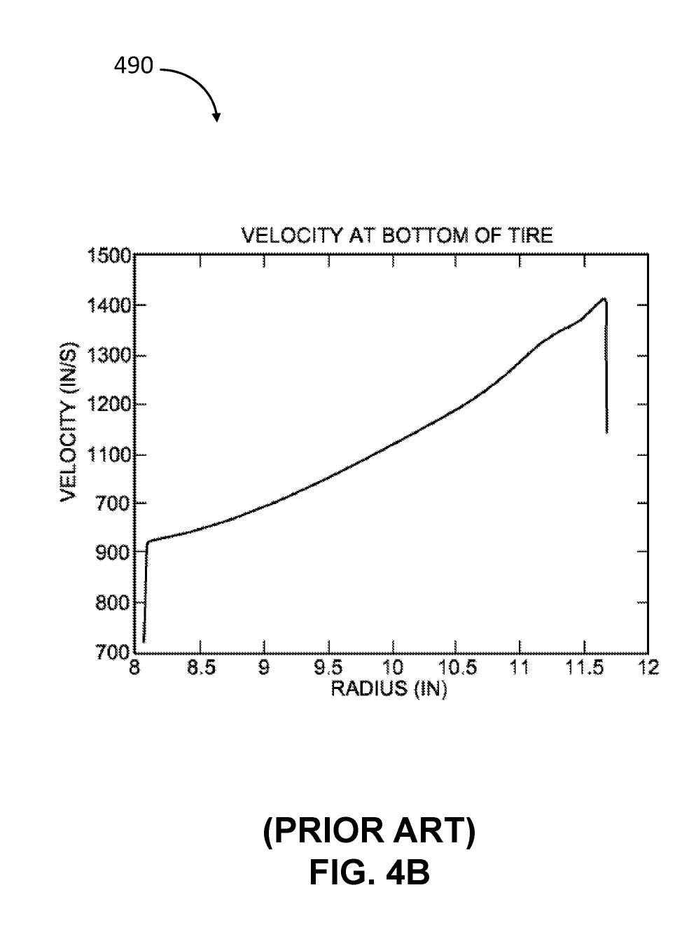

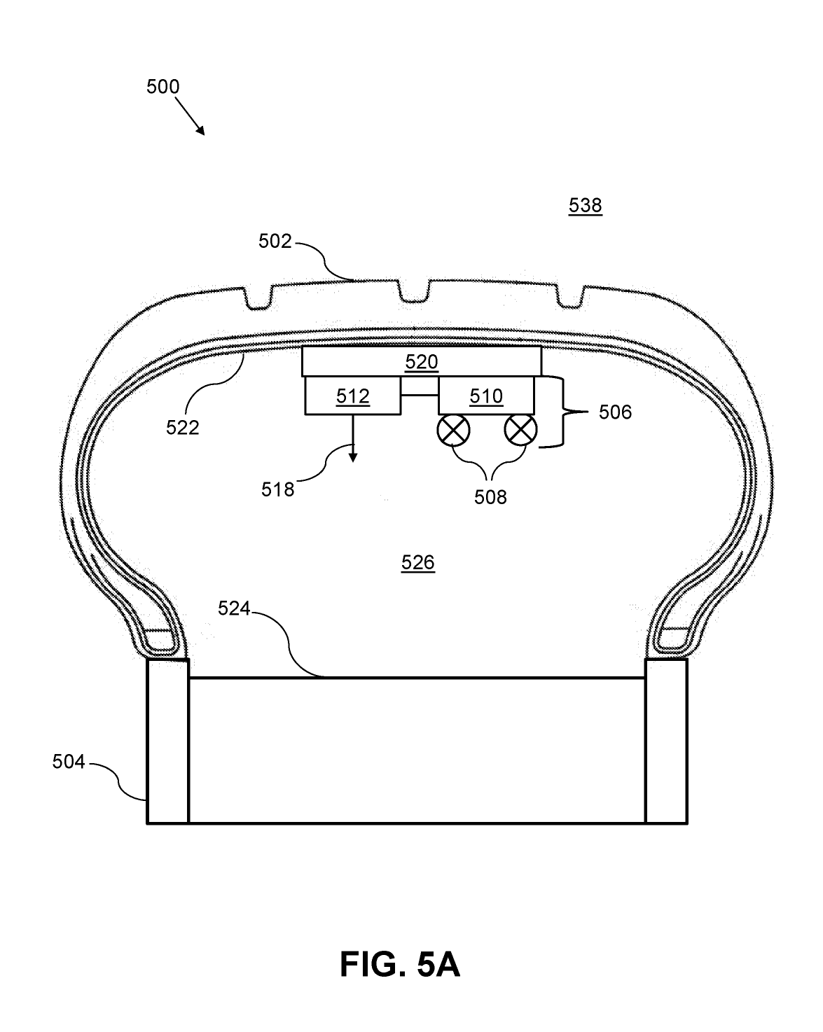

During operation, any given section of tire 100 and adjacent inflation gas 102 may pass by tire footprint 130 once per rotation. A cross-section 200B of tire 100 at or proximate to tire footprint 130 may have a smaller area than a cross-section 200A of the tire, e.g., at crown 132 distal from tire footprint 130 due to deformation of tire 100 at tire footprint 130. Diminished cross-sectional area 200B in tire footprint 130 may cause a local increase in gas flow velocity of inflation gas 102 compared to relative to fluid flow 104 elsewhere in the internal cavity 430 (illustrated in FIG. 4A). Such an increase in gas flow velocity at tire footprint 130 in cross-sectional area 200B may be demonstrated by computational fluid dynamics results 110 in FIGS. 1, 2A, and 2B and in graph 390 of FIG. 3B.

FIG. 4 illustrates a tire-wheel system 400 in cross-section. Tire-wheel system 400 may include a wheel 410 and a tire 420. Tire 420 may be a pneumatic tire adapted for inflation with inflation gas 431. In other embodiments (not shown), tire 400 may be a run flat tire, fixed-inflation tire, or the like. As tire-wheel system 400 rotates during operation, inflation gas 431 may tend to rotate within tire 420 effective to form a fluid flow (e.g., fluid flow 104 in FIG. 3A). Wheel 410 may include a rim portion 412 adapted for engagement with tire 420 and a plate portion 416 adapted for engagement with an associated vehicle (not shown). Rim portion 412 may include an annular exterior surface 413 extending around axis 402 in a closed loop, having a wheel circumference that defines a wheel circumferential direction. While rim portion 412 is shown varying in radius from axis 402 such that the wheel circumference varies with axial position, the circumferential direction taken at any given axial position may be the same as that at any other axial position. Tire 420 and wheel 410 may together define an internal cavity 430. Internal cavity 430 may be defined by a set of surfaces including inner surfaces of tire 420 and wheel 410. Internal cavity 430 may be defined by an annular inner surface 424 of tire 420 opposite a tread surface 426 of tire 420, a first sidewall internal surface 425 opposite first sidewall surface 427 of tire 420, and by wheel rim surface 413 of wheel 410. Internal cavity 430 may be substantially isolated from the surrounding environment 440 by tire 420 and the wheel 410. Internal cavity 430 may contain air or be inflated with inflation gas 431 to some pressure above that of surrounding environment 440.

During operation, the individual elements comprising tire wheel system 400 may undergo rotation at a common rate such that all elements may have substantially the same angular velocity. Tire 410 may include an axis of operational rotation 402. Tire 410 may include an annular interior surface 424 that extends around axis 402 in a closed loop to define a circumference and a tire circumferential direction. Tire 420 may include a tire radial direction 474 that is mutually perpendicular to both axis 402 and the tire circumferential direction. Annular interior surface 424 may loop around the tire fully to define a circumference and an interior surface circumferential direction along the annular interior surface in the direction of the circumference. Annular interior surface 424 may be adapted for engagement to wheel 410. Annular interior surface 424 may be engaged with wheel rim surface 413 indirectly by first sidewall surface 427 and by second tire sidewall 428.

Inflation air 431 of rotating pneumatic tire-wheel system 400 may tend to rotate along with a neighboring material, e.g., annular interior surface 424, wheel rim surface 413, sidewall internal surface 425, an additional portion of inflation gas 431, and the like. In pneumatic tire-wheel system 400, internal cavity 430 may be bounded radially by annular interior surface 424, defining an outer radial limit, and wheel rim surface 413, defining a smaller inner radial limit. During operation, annular interior surface 424 and wheel rim surface 413 may rotate at substantially the same angular velocity. Since annular interior surface 424 and wheel rim surface 413 may rotate at substantially the same angular velocity but differ in their distance from axis of rotation 402, annular interior surface 424 may move at a higher linear velocity compared to wheel rim surface 413. The portion of the inflation gas 431 closest to annular interior surface 424 may tend to move at a rate along with annular interior surface 424, while a portion of the inflation gas 431 closest to wheel rim surface 413 may tend to move at a rate along with the wheel rim surface 413. Consequently, the portion of the inflation gas 431 closest to annular interior surface 424 may tend to move faster than the portion of the inflation gas 431 closest to wheel rim surface 413. Such a trend in gas velocities may be demonstrated by computational fluid dynamics results 110 shown in FIGS. 1, 2A, and 2B and in graph 490 in FIG. 4B.

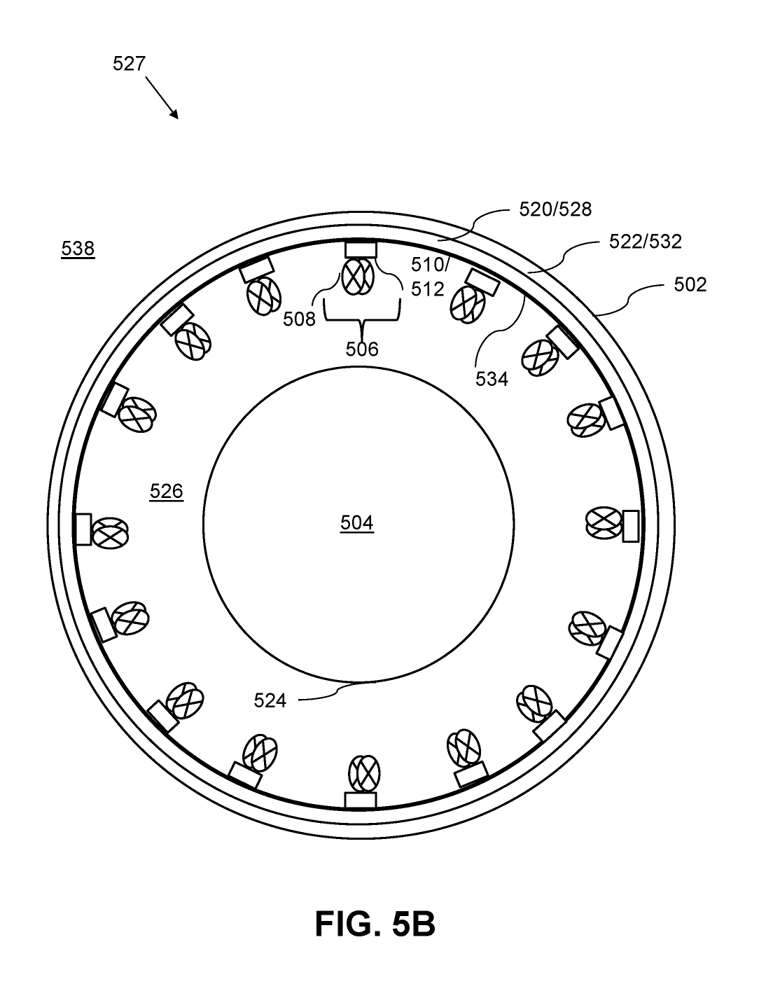

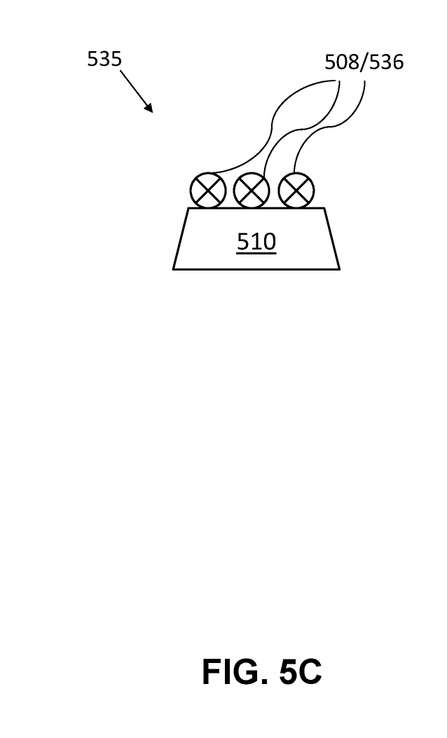

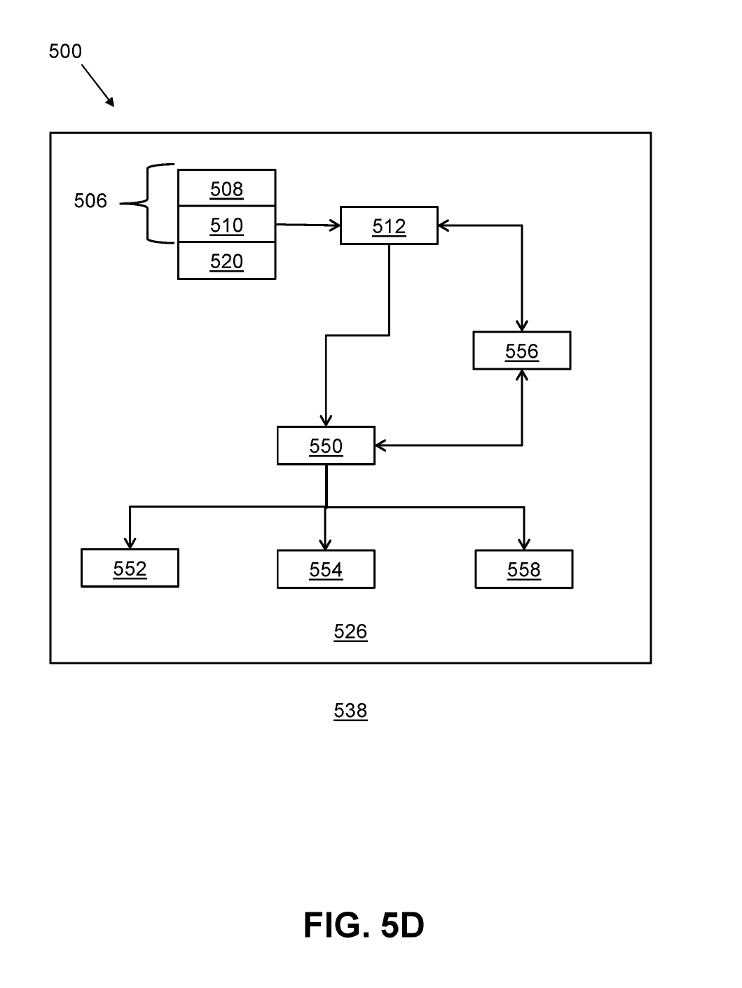

In various embodiments, an electrical system 500 configured to operate inside a tire 502 mounted to a wheel 504 is provided, as illustrated in FIG. 5A. Electrical system 500 may include a plurality of microelectromechanical system (MEMS) devices 506. Each MEMS device 506 may include a gas flow energy receiver 508 mechanically coupled to at least one base 510. Each gas flow energy receiver 508 may be operatively coupled to at least one generator 512. At least one generator 512 may be configured to convert gas flow energy to electrical energy. At least one generator 512 may be configured to direct electrical energy to an electrical output 518 of at least one generator 512. Electrical system 500 may include a support feature 520. Support feature 520 may be configured to mount at least one base 510 of plurality of MEMS devices 506 to one or more of an inner surface 522 of tire 502 or an inner surface 524 of the wheel 504. Plurality of MEMS devices 506 may be mounted effective to place gas flow energy receivers 508 in a gas flow space 526 of tire 502 mounted to wheel 504. Gas flow space 526 may be defined between inner surfaces 522 and 524 of tire 502 and wheel 504.

In some embodiments, two or more gas flow energy receivers 508 may be configured for efficient operation at two or more different gas flow rates. For example, one gas flow energy receiver 508 may be configured for efficient operation at a low gas flow rate and another gas flow energy receiver 508 may be configured for efficient operation at a comparatively higher gas flow rate. Gas flow energy receivers 508 may be configured for efficient operation at different gas flow rates by one or more of: different blade designs such as number or pitch of blades or different blade lengths, different locations within tire 502, and the like.

In various embodiments, support feature 520 may include a hoop 528, as illustrated in side view 527 in FIG. 5B. Hoop 528 may be flexible. Hoop 528 may be configured to be attached to inner surface 522 of tire 504 and/or inner surface 524 of wheel 504. Plurality of MEMS devices 506 may be distributed about hoop 528. Hoop 528 may be configured to be attached to a radially inward surface 522 of tire 502 about at least a portion of a circumference 532 of radially inward surface 522. Hoop 528 may be mounted inside gas flow space 526 of tire 502 mounted to wheel 504 such that hoop 528 comprises a radially inward surface 534. Plurality of MEMS devices 506 may be affixed to a radially inward surface 534 of hoop 528. Alternatively, or in addition, support feature 520, e.g., hoop 528, may include an elastic material operable to expand in diameter during rotation of tire 502 effective to engage inner surface 522 during rotation. Alternatively, or in addition, support feature 520 may include one or more of: an adhesive, a mechanical fastener, a molding surface configured to be received into a molded receptacle of tire 502 or wheel 504; or a component configured to be integrally formed into tire 502 or wheel 504.

In some embodiments, plurality of MEMS devices 506 may include a plurality of MEMS windmills 535, as illustrated in FIG. 5C. Each of plurality of MEMS devices 506 may include a three-dimensional structure formed from photo-lithographical production of two-dimensional components, e.g., airfoil 536 and base 510. Each of plurality of MEMS devices 506 may exclude piezoelectric material. Airfoil 536 may be configured to move in response to the gas flow. Airfoil 536 may include a flexible metal or flexible metal alloy. Airfoil 536 may include nickel or a nickel alloy. Airfoil 536 may exclude piezoelectric material. Each gas flow energy receiver 508 may include airfoil 536 configured as one or more of: an axial flow airfoil, a crossflow flow airfoil, or a helical airfoil.

In several embodiments, electrical system 500 may be configured to operate in at least partial electrical isolation with respect to an environment 538 outside tire 502 mounted to wheel 504. Electrical system 500 may be configured to operate substantially electrically isolated with respect to environment 538 outside tire 502 mounted to wheel 504. Electrical system 500 may be electrically isolated with respect to environment 538 outside tire 502 mounted to wheel 504.

In various embodiments, a tire system is provided, which may include electrical system 500 together with tire 502. In some embodiments, a wheel system is provided, which may include electrical system 500 together with wheel 504. In several embodiments, a tire and wheel system is provided, which may include electrical system 500 together with tire 502 and wheel 504. In various embodiments, tire 502 may be a pneumatic tire.

In some embodiments, gas flow space 526 may support a gas flow caused at least in part by relative motion between the inner surfaces 522, 524 of tire 502 and/or wheel 504 and gas in gas flow space 526.

For conventional large scale windmills, taller windmills may be better because average wind speeds tend to increase with height from the ground. The small size of plurality of MEMS devices 506 may be a significant disadvantage in this view. Surprisingly and unexpectedly compared to conventional windmills, the small size of plurality of MEMS devices 506 may be advantageous in the context of gas flow in tire 502. As discussed herein, gas flow rates in a rotating tire may increase in a direction radially outward towards inner surface 522 of tire 502. Thus, the smaller each of plurality of MEMS devices 506 is, the closer gas flow energy receiver 508 may be to inner surface 522 of tire 502 and the corresponding region of highest gas flow. In various embodiments, gas flow energy receiver 508 is within a distance in millimeters of inner surface 522 of less than about one or more of 30, 25, 20, 15, 14, 13, 12, 11, 10, 9, 8, 7, 6, 5, 4, 3, 2, or 1, for example, within about 10 millimeters or within about 5 millimeters.

For example, gas flow space 526 may be characterized by an average total gas flow rate under a given rotational operation of tire 502 mounted to wheel 504. Plurality of MEMS devices 506 may be mounted effective to place gas flow energy receivers 508 in a subset of gas flow space 526. Such a subset of gas flow space 526 may be characterized by an average subset gas flow rate under the given rotational operation of tire 502 mounted to wheel 504. The average subset gas flow rate may be greater compared to the average total gas flow rate of gas flow space 526. In this manner, gas flow energy receivers 508 may be positioned to take advantage of locally higher gas flow rates according to the shape of tire 502 and wheel 504 in combination with tire deformation and rotational motion under the given rotational operation of tire 502 mounted to wheel 504. In various embodiments, for example conditions, locally higher gas flow rates may be found at increasing radius from the center of tire 502/wheel 504, for example, in proximity to inner surface 522 of tire 502.

In various embodiments, at least one base 510 may be common to gas flow energy receivers 508 in plurality of MEMS devices 506. For example, plurality of MEMS devices 506 may be mechanically coupled in common to at least one base 510, e.g., as a single base. For example, at least one base 510 may be a wafer, such as one or more of a semiconductor, a ceramic, a glass, a metal, or a polymer. Plurality of MEMS devices 506 may be constructed as a large array 535 of devices 506 in parallel on a wafer in a single sequence of MEMS photolithographic manufacturing steps according to conventional MEMS production processes. In some embodiments, at least one base 510 may include a plurality of bases corresponding to plurality of MEMS devices 506. Each MEMS device 506 may include its own corresponding base 510. Suitable MEMS devices in the form of micro windmills have been described. See, for example, Gawel, “Micro-windmills Power Portable Devices,” Electronic Design, Feb. 20, 2014, the entire contents of which are incorporated herein by reference.

In some embodiments, at least one generator 512 may be a single generator common to gas flow energy receivers 508 in plurality of MEMS devices 506 such that plurality of MEMS devices 506 are operatively coupled in common to a single generator 512. Each gas flow energy receiver 508 may be configured to convert gas flow energy to mechanical energy, e.g., rotational energy. Such mechanical energy, e.g., rotational energy may be convertible by the at least one generator 512 to electrical energy. For example, each gas flow energy receiver 508 may be directly coupled to at least one generator 512. Electrical system 500 may further include a mechanical transmission (not shown). The mechanical transmission may be a mechanical transmission manifold configured to couple gas flow energy receivers 508 in plurality of MEMS devices 506 to at least one generator 512 as a single generator. The mechanical transmission may include one or more of: a gear train, an epicyclic gearing, a worm drive, a belt and pulley system, a chain drive, or a mechanical linkage. In several embodiments, at least one generator 512 may be one of a plurality of generators corresponding to plurality of MEMS devices 506 such that each MEMS device 506 includes gas flow energy receiver 508 operatively coupled to one of plurality of corresponding generators. For example, each MEMS device 506 may include its own corresponding generator 512.

In several embodiments, an electrical harness (not shown) may be included. The electrical harness may be configured to electrically couple at least a portion of plurality of corresponding generators 512 in series or in parallel (not shown).

In some embodiments, electrical system 500 may include a controller 550. FIG. 5D is a block diagram of electrical system 500. Controller 550 may be operatively coupled to electrical output 518 of at least one generator 512 effective to power controller 550 with electrical energy. Electrical system 500 may include a sensor 552 operatively coupled to controller 550. Controller 550 may be configured to receive a signal from sensor 552. Sensor 552 may be one or more of: a mechanical sensor, e.g., a mechanical vibration sensor, an electrical sensor, e.g., a Hall effect sensor, an optical sensor, e.g., an infrared photodiode, a thermal sensor, e.g., a thermocouple, a pressure sensor, e.g., a pressure transducer, or a chemical sensor, e.g. a gas composition sensor. For example, the signal from sensor 552 may indicate one or more of: a vibration, an impact, a rotational speed, a linear speed, a temperature, a gas pressure, a gas composition, an actuator state, or a mechanical characteristic of tire rubber. Electrical system 500 may include an actuator 554 operatively coupled to controller 550. Controller 550 may be configured to operate actuator 554 to cause a change in one or more of: a temperature, a gas pressure, a mechanical pressure, a mechanical vibration, a gas composition, a ride characteristic, or a mechanical characteristic of tire rubber. Electrical system 500 may include an electrical storage device 556 operatively coupled to at least one of generator 512 and controller 550. For example, controller 550 may be configured to store and/or withdraw the electrical energy provide by generator 512 using electrical energy storage device 556. Electrical energy storage device 556 may include a rechargeable battery, a capacitor, and the like.

In several embodiments, controller 550 may be configured to be located in gas flow space 526. Electrical system 500 may include a communication module 558. Communication module 558 may be configured to receive or transmit a communication between controller 550 and a location outside of tire 502 mounted to wheel 504. Communication module 558 may employ wired or wireless communications.

In various embodiments, electrical system 500 may include, operatively coupled to controller 550, one or more of sensor 552, actuator 554, electrical energy storage device 556, and communications module 558. For example, controller 550 and communication module 558 may be configured to receive or transmit the communication between controller 550 and a location outside of tire 502 mounted to wheel 504. The communication may include, for example, one or more of: a value sensed by sensor 552, an instruction to control the actuator 554, a state parameter of the actuator 554, a power level of electrical energy storage device 556, and the like. For example, communication module 558 may be configured to receive or transmit a communication between controller 550 and a vehicle information management system, e.g., to communicate a sensor signal to a vehicle driving dynamics computer, to alert a driver to a temperature or pressure condition, and the like.

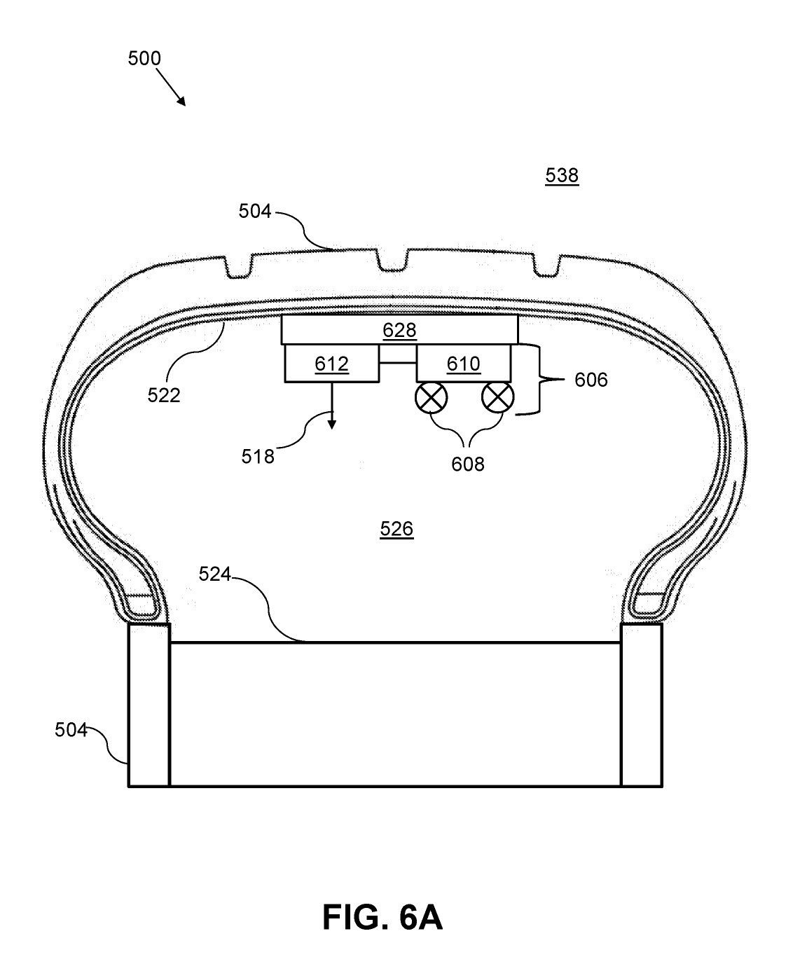

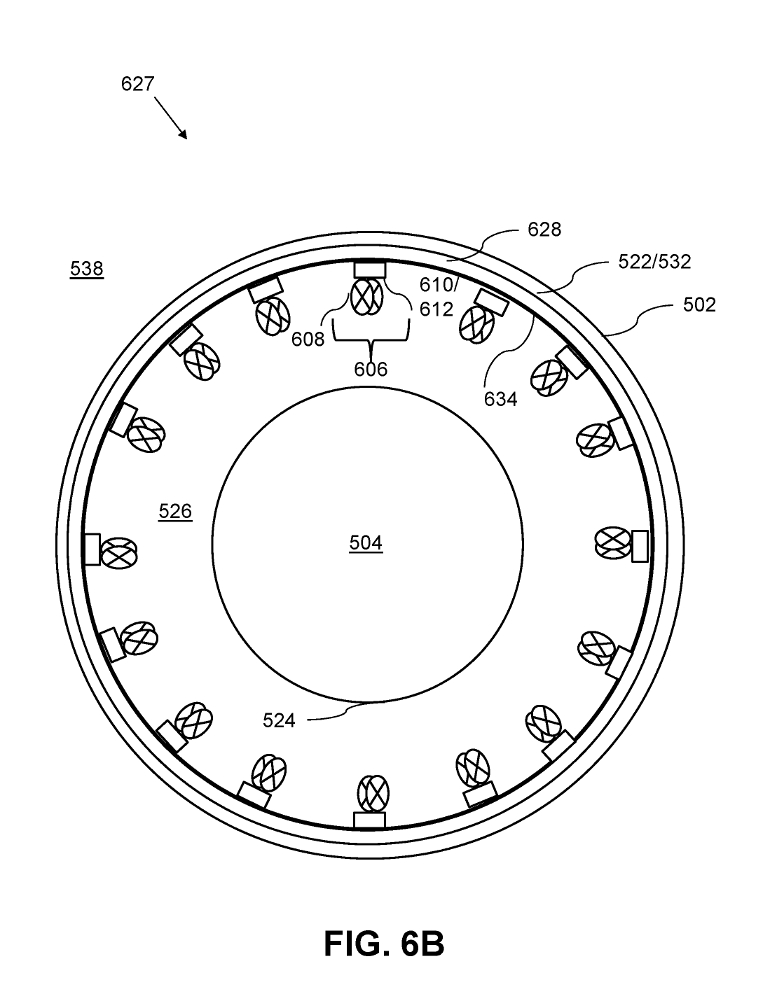

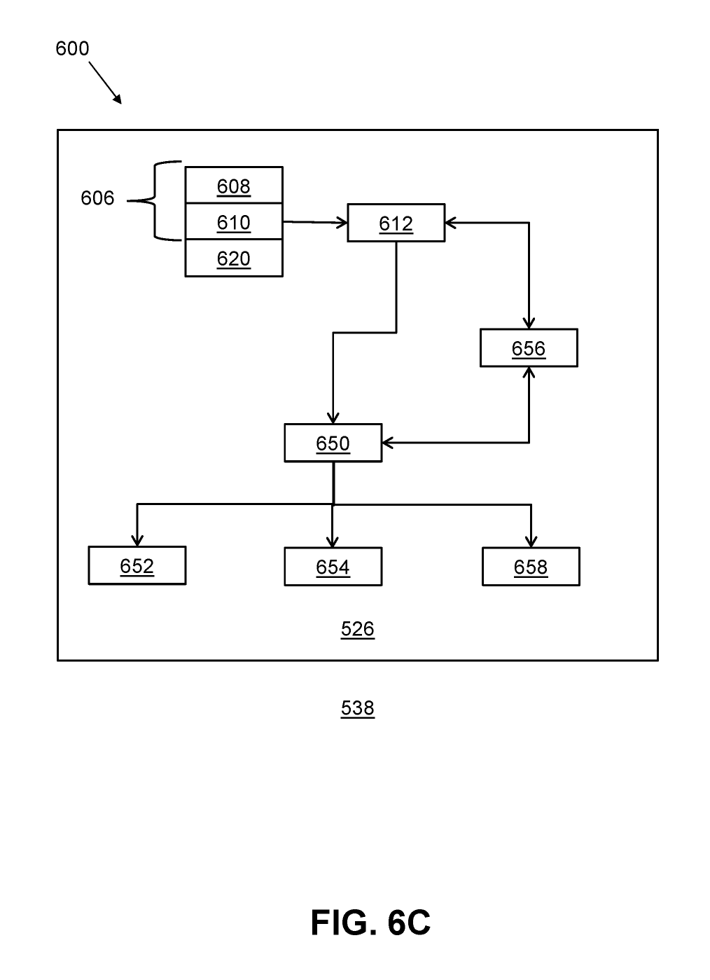

In various embodiments, an electrical system 600 configured to operate inside a tire 502 mounted to a wheel 504 is provided. FIG. 6A depicts an illustration of electrical system 600. Electrical system 600 may include one or more gas flow power devices 606. Each gas flow power device 606 may include a gas flow energy receiver 608 mechanically coupled to a base 610. Each gas flow energy receiver 608 may be operatively coupled to at least one generator 612. At least one generator 612 may be configured to convert received gas flow energy to electrical energy. At least one generator 612 may be configured to direct electrical energy to an electrical output 618 of at least one generator 612. Electrical system 600 may include a hoop 628.

FIG. 6B illustrates hoop 628 and electrical system 600 in side view 627. Hoop 628 may be configured to mount at least one base 610 of gas flow power device 606 to one or more of inner surface 522 of tire 502 or inner surface 524 of wheel 504. Gas flow power device 606 may be mounted effective to place gas flow energy receiver 608 in gas flow space 526 of tire 502 mounted to wheel 504. Gas flow space 526 may be defined between inner surfaces 522 and 524 of tire 502 and wheel 504. A plurality of gas flow power devices 606 may be distributed about hoop 628. Hoop 628 may be configured to be attached to a radially inward surface 522 of tire 502 about at least a portion of a circumference 532 of radially inward surface 522. Hoop 628 may be mounted inside gas flow space 526 of tire 502 mounted to wheel 504 such that hoop 628 comprises a radially inward surface 634. Each gas flow power device 606 may be affixed to a radially inward surface 634 of hoop 628. Alternatively, or in addition, hoop 268 may include an elastic material operable to expand in diameter during rotation of tire 502 effective to engage inner surface 522 during rotation.

In various embodiments, the features of electrical system 500 as described herein may be individually or jointly combined, embodied, or implemented in electrical system 600.

For example, as with hoop 528, hoop 628 may be flexible. Hoop 628 may be configured to be attached to inner surface 522 of tire 504 and/or inner surface 524 of wheel 504. Hoop 628 may be configured to be attached to inner surface 522 of tire 502. Gas flow power devices 606 may be distributed about hoop 628. Hoop 628 may be configured to be attached to a radially inward surface 522 of tire 502 about at least a portion of a circumference 532 of radially inward surface 522. Hoop 628 may be mounted inside gas flow space 526 of tire 502 mounted to wheel 504 such that hoop 628 comprises a radially inward surface 634. Gas flow power devices 606 may be affixed to a radially inward surface 634 of hoop 628. Alternatively, or in addition, support feature 520, e.g., hoop 628, may include an elastic material operable to expand in diameter during rotation of tire 502 effective to engage inner surface 522 during rotation. Alternatively, or in addition, support feature 520 may include one or more of: an adhesive, a mechanical fastener, a molding surface configured to be received into a molded receptacle of tire 502 or wheel 504; or a component configured to be integrally formed into tire 502 or wheel 504.

In some embodiments, gas flow power devices 606 may include a plurality of MEMS windmills. Each of gas flow power devices 606 may include a three-dimensional structure formed from photo-lithographical production of two-dimensional components, e.g., airfoil 536. Each of gas flow power devices 606 may exclude piezoelectric material.

In several embodiments, electrical system 600 may be configured to operate in at least partial electrical isolation with respect to an environment 538 outside tire 502 mounted to wheel 504. Electrical system 600 may be configured to operate substantially electrically isolated with respect to environment 538 outside tire 502 mounted to wheel 504. Electrical system 600 may be electrically isolated with respect to environment 538 outside tire 502 mounted to wheel 504.

In various embodiments, a tire system is provided, which may include electrical system 600 together with tire 502. In some embodiments, a wheel system is provided, which may include electrical system 600 together with wheel 504. In several embodiments, a tire and wheel system is provided, which may include electrical system 600 together with tire 502 and wheel 504. In various embodiments, tire 502 may be a pneumatic tire.

In some embodiments, gas flow space 526 may support a gas flow caused at least in part by relative motion between the inner surfaces 522, 524 of tire 502 and/or wheel 504 and gas in gas flow space 526.

For conventional large scale windmills, taller windmills are better because average wind speeds tend to increase with height from the ground. A small size of gas flow power devices 606 may be a significant disadvantage in this view. Surprisingly and unexpectedly compared to conventional windmills, the small size of gas flow power devices 606 becomes a distinct advantage in the context of gas flow in tire 502. In a rotating tire, gas flow rates increase in a direction radially outward towards inner surface 522 of tire 502. Thus, the smaller each of gas flow power devices 606 is, the closer gas flow energy receiver 608 may be to inner surface 522 of tire 502 and the corresponding region of highest gas flow. In various embodiments, gas flow energy receiver 608 is within a distance in millimeters of inner surface 522 of less than about one or more of 30, 25, 20, 15, 14, 13, 12, 11, 10, 9, 8, 7, 6, 5, 4, 3, 2, or 1, for example, within about 10 millimeters or within about 5 millimeters.

For example, gas flow space 526 may be characterized by an average total gas flow rate under a given rotational operation of tire 502 mounted to wheel 504. Gas flow power devices 606 may be mounted effective to place gas flow energy receivers 608 in a subset of gas flow space 526. Such a subset of gas flow space 526 may be characterized by an average subset gas flow rate under the given rotational operation of tire 502 mounted to wheel 504. The average subset gas flow rate may be greater compared to the average total gas flow rate of gas flow space 526. In this manner, gas flow energy receivers 608 may be positioned to take advantage of locally higher gas flow rates according to the shape of tire 502 and wheel 504 in combination with tire deformation and rotational motion under the given rotational operation of tire 502 mounted to wheel 504. In various embodiments, for example conditions, locally higher gas flow rates may be found at increasing radius from the center of tire 502/wheel 504, for example, in proximity to inner surface 522 of tire 502.

In various embodiments, at least one base 610 may be common to gas flow energy receivers 608 in gas flow power devices 606. For example, gas flow power devices 606 may be mechanically coupled in common to at least one base 610, e.g., as a single base. For example, at least one base 610 may be a wafer, such as one or more of a semiconductor, a ceramic, a glass, a metal, or a polymer. Gas flow power devices 606 may be constructed as a large array of devices 606 in parallel on a wafer in a single sequence of manufacturing steps, e.g., according to conventional MEMS photolithographic production processes. In some embodiments, at least one base 610 may include a plurality of bases corresponding to gas flow power devices 606. Each gas flow power device 606 may include its own corresponding base 610.

In some embodiments, at least one generator 612 may be a single generator common to gas flow energy receivers 608 in gas flow power devices 606 such that gas flow power devices 606 may be operatively coupled in common to a single generator 612. Each gas flow energy receiver 608 may be configured to convert gas flow energy to mechanical energy, e.g., rotational energy. Such mechanical energy, e.g., rotational energy may be convertible by the at least one generator 612 to electrical energy. For example, each gas flow energy receiver 608 may be directly coupled to at least one generator 612. Electrical system 600 may further include a mechanical transmission (not shown). The mechanical transmission may be a mechanical transmission manifold configured to couple gas flow energy receivers 608 in gas flow power devices 606 to at least one generator 612 as a single generator. The mechanical transmission may include one or more of: a gear train, an epicyclic gearing, a worm drive, a belt and pulley system, a chain drive, or a mechanical linkage. In several embodiments, at least one generator 612 may be one of a plurality of generators 612 corresponding to gas flow power devices 606 such that each gas flow power device 606 may include gas flow energy receiver 608 operatively coupled to one of plurality of corresponding generators 612. Each gas flow power device 606 may include its own corresponding generator 612.

In several embodiments, an electrical harness (not shown) may be included. The electrical harness may be configured to electrically couple at least a portion of plurality of corresponding generators 612 in series, or in parallel.

In various embodiments, each gas flow energy receiver 608 may include an airfoil (not shown) configured to move in response to the gas flow. The airfoil may include a flexible metal or flexible metal alloy. The airfoil may include nickel or a nickel alloy. The airfoil may exclude piezoelectric material. Each gas flow energy receiver 608 may include the airfoil configured as one or more of: an axial flow airfoil, a crossflow flow airfoil, or a helical airfoil.

In some embodiments, electrical system 600 may include a controller 650. Controller 650 may be operatively coupled to electrical output 618 of at least one generator 612 effective to power controller 650 with electrical energy. Electrical system 600 may include a sensor 652 operatively coupled to controller 650. Controller 650 may be configured to receive a signal from sensor 652. Sensor 652 may be one or more of: a mechanical sensor, e.g., a mechanical vibration sensor, an electrical sensor, e.g., a Hall effect sensor, an optical sensor, e.g., an infrared photodiode, a thermal sensor, e.g., a thermocouple, a pressure sensor, e.g., a pressure transducer, or a chemical sensor, e.g. a gas composition sensor. For example, the signal from sensor 652 may indicate one or more of: a vibration, an impact, a rotational speed, a linear speed, a temperature, a gas pressure, a gas composition, an actuator state, or a mechanical characteristic of tire rubber. Electrical system 600 may include an actuator 654 operatively coupled to controller 650. Controller 650 may be configured to operate actuator 654 to cause a change in one or more of: a temperature, a gas pressure, a mechanical pressure, a mechanical vibration, a gas composition, a ride characteristic, or a mechanical characteristic of tire rubber. Electrical system 600 may include an electrical storage device 656 operatively coupled to at least one of generator 612 and controller 650. For example, controller 650 may be configured to store and/or withdraw the electrical energy provide by generator 612 using electrical energy storage device 656. Electrical energy storage device 656 may include a rechargeable battery, a capacitor, and the like.

In several embodiments, controller 650 may be configured to be located in gas flow space 526. Electrical system 600 may include a communication module 658. Communication module 658 may be configured to receive or transmit a communication between controller 650 and a location outside of tire 502 mounted to wheel 504. Communication module 658 may employ wired or wireless communications.

In various embodiments, electrical system 600 may include, operatively coupled to controller 650, one or more of sensor 652, actuator 654, electrical energy storage device 656, and communications module 658. For example, controller 650 and communication module 658 may be configured to receive or transmit the communication between controller 650 and a location outside of tire 502 mounted to wheel 504. The communication may include, for example, one or more of: a value sensed by sensor 652, an instruction to control the actuator 654, a state parameter of the actuator 654, a power level of electrical energy storage device 656, and the like. For example, communication module 658 may be configured to receive or transmit a communication between controller 650 and a vehicle information management system, e.g., to communicate a sensor signal to a vehicle driving dynamics computer, to alert a driver to a temperature or pressure condition, and the like.

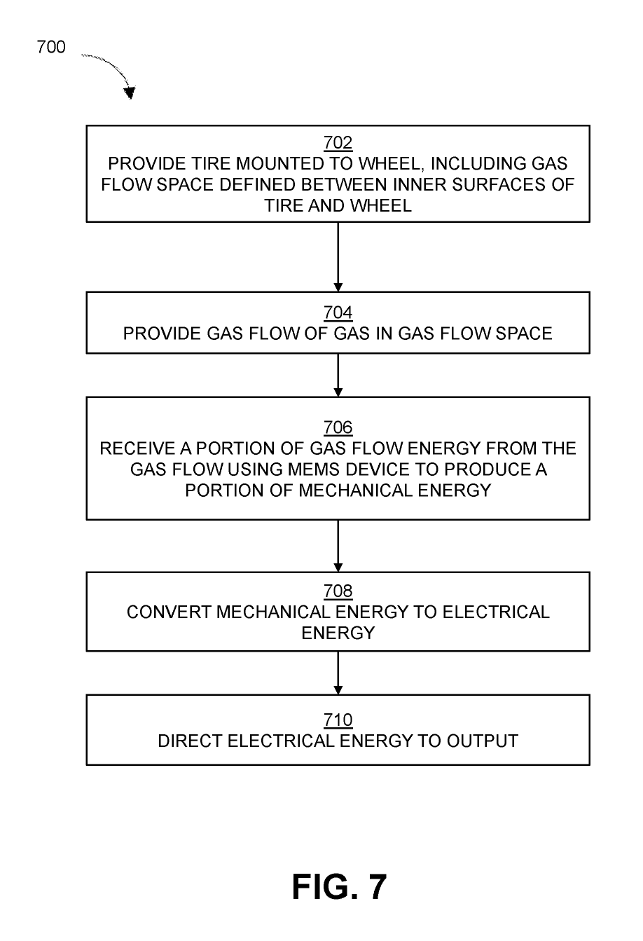

In various embodiments, a method 700 for operating an electrical system inside a tire mounted to a wheel is provided. FIG. 7 depicts a flow chart of method 700. Method 700 may include 702 providing the tire mounted to the wheel. A gas flow space may be defined between the inner surfaces of the wheel and the tire. The method may include 704 providing a gas flow caused at least in part by relative motion. The relative motion may be between: gas in the gas flow space; and an inner surface of the tire and/or an inner surface of the wheel. Method 700 may include 706 receiving a portion of gas flow energy from the gas flow using a microelectromechanical system (MEMS) device to produce a portion of mechanical energy. The MEMS device may include a gas flow energy receiver. The method may include 708 converting the mechanical energy using an electrical generator to electrical energy. The method may include 710 directing the electrical energy to an output of the electrical generator.

Method 700 may include providing the MEMS device mounted via at least one base to the inner surface of the tire and/or the inner surface of the wheel. The MEMS device may be mounted via the at least one base using one or more of: an adhesive, a mechanical fastener, a molding surface configured to be received into a molded receptacle of the tire or the wheel; or a component configured to be integrally formed into the tire or the wheel.

Method 700 may include providing MEMS device mounted via at least one base to the inner surface of the tire and/or the inner surface of the wheel, the MEMS device being mounted via the at least one base using a hoop. The hoop may be flexible. The plurality of MEMS devices may be distributed about the hoop. Method 700 may include providing the hoop attached to the inner surface of the wheel and/or the inner surface of the tire. Method 700 may include providing the hoop attached to the inner surface of the tire at a crown of the tire. For example, the method may include operating each gas flow energy receiver within a distance in millimeters of the inner surface of the tire of less than about one or more of 30, 25, 20, 15, 14, 13, 12, 11, 10, 9, 8, 7, 6, 5, 4, 3, 2, or 1. Method 700 may include providing the hoop attached to a radially inward surface of the tire about at least a portion of a circumference of the radially inward surface of the tire. Method 700 may include providing the plurality of MEMS devices being affixed to a radially inward surface of the hoop. The hoop may include an elastic material. Method 700 may include expanding the hoop in diameter during rotation of the tire effective to engage the inner surface of the tire during rotation of the tire.

In various embodiments, the plurality of MEMS devices may include a plurality of MEMS windmills. Each of the plurality of MEMS devices may include a three-dimensional structure formed from photo-lithographical production of two-dimensional components. Method 700 may include excluding piezoelectric material from the plurality of MEMS devices.

In several embodiments, method 700 may include operating in at least partial electrical isolation with respect to an environment outside the tire mounted to the wheel. Method 700 may include operating substantially electrically isolated with respect to an environment outside the tire mounted to the wheel. Method 700 may include operating electrically isolated with respect to an environment outside the tire mounted to the wheel. The tire may be a pneumatic tire.

In some embodiments, the gas flow space may be characterized by an average total gas flow rate under a given rotational operation of the tire mounted to the wheel. Method 700 may include operating the plurality of MEMS devices in a subset of the gas flow space characterized by an average subset gas flow rate greater compared to the average total gas flow rate of the gas flow space.

In various embodiments, method 700 may include receiving gas flow energy using an airfoil configured to move in response to the gas flow. The airfoil may include a flexible metal or metal alloy. The airfoil may include nickel or a nickel alloy. Method 700 may include excluding piezoelectric material from the airfoil. The airfoil may include one or more of: an axial flow airfoil, a crossflow flow airfoil, or a helical airfoil.

In several embodiments, method 700 may include operating a controller with the electrical energy. Method 700 may include operating the controller to receive a signal from a sensor. Receiving the signal may include receiving a parameter indicative of a property that is one or more of: mechanical, electrical, optical, thermal, pressure, or chemical. Method 700 may include operating the controller to determine, from the signal, one or more of: a vibration, an impact, a rotational speed, a linear speed, a temperature, a gas pressure, a gas composition, an actuator state, or a mechanical characteristic of tire rubber. Method 700 may include operating the controller to control an actuator to cause a change in one or more of: a temperature, a gas pressure, a mechanical pressure, a mechanical vibration, a gas composition, a ride characteristic, or a mechanical characteristic of tire rubber. Method 700 may include operating the controller to store and/or withdraw the electrical energy using an electrical energy storage device. Method 700 may include receiving or transmitting a communication between the controller and a location outside of the tire mounted to the wheel. Receiving or transmitting the communication may be conducted via a wired or wireless communication module, e.g., a wireless communication module.

To the extent that the term “includes” or “including” is used in the specification or the claims, it is intended to be inclusive in a manner similar to the term “comprising” as that term is interpreted when employed as a transitional word in a claim. Furthermore, to the extent that the term “or” is employed (e.g., A or B) it is intended to mean “A or B or both.” When the applicants intend to indicate “only A or B but not both” then the term “only A or B but not both” will be employed. Thus, use of the term “or” herein is the inclusive, and not the exclusive use. See Bryan A. Garner, A Dictionary of Modern Legal Usage 624 (2d. Ed. 1995). Also, to the extent that the terms “in” or “into” are used in the specification or the claims, it is intended to additionally mean “on” or “onto.” To the extent that the term “selectively” is used in the specification or the claims, it is intended to refer to a condition of a component wherein a user of the apparatus may activate or deactivate the feature or function of the component as is necessary or desired in use of the apparatus. To the extent that the terms “coupled” or “operatively connected” are used in the specification or the claims, it is intended to mean that the identified components are connected in a way to perform a designated function. To the extent that the term “substantially” is used in the specification or the claims, it is intended to mean that the identified components have the relation or qualities indicated with degree of error as would be acceptable in the subject industry.

As used in the specification and the claims, the singular forms “a,” “an,” and “the” include the plural unless the singular is expressly specified. For example, reference to “a compound” may include a mixture of two or more compounds, as well as a single compound.

As used herein, the term “about” in conjunction with a number is intended to include 35 10% of the number. In other words, “about 10” may mean from 9 to 11.

As used herein, the terms “optional” and “optionally” mean that the subsequently described circumstance may or may not occur, so that the description includes instances where the circumstance occurs and instances where it does not.

The various aspects and embodiments disclosed herein are for purposes of illustration and are not intended to be limiting, with the true scope and spirit being indicated by the following claims.

1. An electrical system configured to operate inside a tire that is mounted to a wheel, comprising:
a plurality of microelectromechanical system (MEMS) devices,
each MEMS device comprising a gas flow energy receiver mechanically coupled to at least one base,
each gas flow energy receiver being operatively coupled to at least one generator, the at least one generator being configured to convert gas flow energy to electrical energy,
the at least one generator being configured to direct the electrical energy to an electrical output of the at least one generator; and
a support feature configured to mount the at least one base of the plurality of MEMS devices to one or more of an inner surface of the tire and an inner surface of the wheel, the plurality of MEMS devices being mounted effective to place the gas flow energy receivers in a gas flow space of the tire mounted to the wheel, the gas flow space being defined between the inner surfaces of the wheel and the tire mounted thereto.

2. The electrical system of claim 1, the support feature comprising a flexible hoop.

3. The electrical system of claim 1, the support feature comprising a hoop configured to be attached to the inner surface of the wheel and/or the inner surface of the tire.

4. The electrical system of claim 1, the support feature comprising a hoop, the plurality of MEMS devices being distributed about the hoop.

5. (canceled)

6. The electrical system of claim 1, the support feature comprising a hoop configured to be attached to a radially inward surface of the tire about at least a portion of a circumference of the radially inward surface of the tire.

7. The electrical system of claim 1, the support feature comprising a hoop configured to be mounted inside the gas flow space of the tire mounted to the wheel such that the hoop comprises a radially inward surface, the plurality of MEMS devices being affixed to the radially inward surface of the hoop.

8. The electrical system of claim 1, the support feature comprising an elastic material operable to expand in diameter during rotation of the tire effective to engage the inner surface of the tire during rotation of the tire.

9. The electrical system of claim 1, the support feature comprising one or more of: an adhesive, a mechanical fastener, a molding surface configured to be received into a molded receptacle of the tire or the wheel; or a component configured to be integrally formed into the tire or the wheel.

10. The electrical system of claim 1, the plurality of MEMS devices comprising a plurality of MEMS windmills.

11-32. (canceled)

33. The electrical system of claim 1, each gas flow energy receiver comprising an airfoil configured to move in response to the gas flow.

34-46. (canceled)

47. An electrical system configured to operate inside a tire mounted to a wheel, comprising:
one or more gas flow power devices, the one or more gas flow power devices each comprising a gas flow energy receiver mechanically coupled to a base, the gas flow energy receiver being operatively coupled to at least one generator, the at least one generator being configured to convert received gas flow energy to electrical energy to be output at an electrical output of the at least one generator;
a hoop configured to mount the at least one base of the plurality of gas flow power devices to one or more of an inner surface of the tire or an inner surface of the wheel, the plurality of gas flow power devices being mounted effective to place the gas flow energy receivers in a gas flow space of the tire mounted to the wheel, the gas flow space being defined between the inner surfaces of the wheel and the tire mounted thereto.

48. The electrical system of claim 47, the hoop being flexible.

49. The electrical system of claim 47, the hoop being configured to be attached to the inner surface of the wheel and/or the inner surface of the tire.

50. The electrical system of claim 47, the plurality of gas flow power devices being distributed about the hoop.

51. (canceled)

52. The electrical system of claim 47, the hoop being configured to be attached to a radially inward surface of the tire about at least a portion of a circumference of the radially inward surface of the tire.

53. The electrical system of claim 47, the hoop being configured to be mounted inside the gas flow space of the tire mounted to the wheel such that the hoop structure comprises a radially inward surface, the plurality of gas flow power devices being affixed to the radially inward surface of the hoop.

54. The electrical system of claim 47, the support feature comprising an elastic material operable to expand in diameter during rotation of the tire effective to engage the inner surface of the tire during rotation of the tire.

55. (canceled)

56. The electrical system of claim 47, the plurality of gas flow power devices comprising a plurality of MEMS windmills.

57-66. (canceled)

67. The electrical system of claim 47, the at least one base being common to the gas flow energy receivers in the plurality of gas flow power devices such that the plurality of gas flow power devices are mechanically coupled in common to the at least one base.

68-78. (canceled)

79. The electrical system of claim 47, each gas flow energy receiver comprising an airfoil configured to move in response to the gas flow.

80-123. (canceled)
